(19) United States
(12) Patent Application Publication
(10) Pub. No.: US 2017/0362412 A1
(43) Pub. Date: Dec. 21, 2017

(54) COMPOSITION FOR FILM FORMATION, AND PATTERN-FORMING METHOD

(71) Applicant: JSR Corporation, Tokyo (JP)

(72) Inventors: Shunsuke Kurita, Tokyo (JP); Hisashi Nakagawa, Tokyo (JP); Tatsuya Sakai, Tokyo (JP)

(73) Assignee: JSR CORPORATION, Tokyo (JP)

(21) Appl. No.: 15/689,662

(22) Filed: Aug. 29, 2017

Related U.S. Application Data
(62) Division of application No. 14/671,255, filed on Mar. 27, 2015.

(30) Foreign Application Priority Data
Apr. 2, 2014 (JP) 2014-076568
Mar. 10, 2015 (JP) 2015-047501

(51) Int. Cl. C08K 5/56; G03F 7/40

(52) U.S. Cl. CPC C08K 5/56; G03F 7/40

(57) ABSTRACT

A composition for film formation includes a hydrolysis compound and a solvent composition. The hydrolysus compound is a hydrolysis product of a metal compound including a hydrolyzable group, a hydrolytic condensation product of the metal compound, a condensation product of the metal compound and a compound represented by formula (1), or a combination thereof. The metal compound includes a metal element from group 3, 4, 5, 6, 7, 8, 9, 10, 11, 12 or 13, or a combination thereof. The solvent composition includes an alcohol organic solvent, and a non-alcohol organic solvent that does not include an alcoholic hydroxyl group and that include a group including a hetero atom.

R¹X¹)ₙ (1)

### CROSS-REFERENCE TO RELATED APPLICATIONS

The present application is a divisional application of U.S. patent application Ser. No. 14/671,255 filed Mar. 27, 2015, which claims priority to Japanese Patent Application No. 2014-076568, filed Apr. 2, 2014, and to Japanese Patent Application No. 2015-047501, filed Mar. 10, 2015. The contents of these applications are incorporated herein by reference in their entirety.

### BACKGROUND OF THE INVENTION

### Field of the Invention

The present invention relates to a composition for film formation, and a pattern-forming method.

### Discussion of the Background

Miniaturization of semiconductor devices and the like has been accompanied by use of multilayer resist processes for attaining a high degree of integration. In the multilayer resist processes, an inorganic film is provided on a substrate using an inorganic film-forming composition, and a resist film that differs in etching rate from the inorganic film is provided on the inorganic film using an organic material. A resist pattern is formed on the resist film, and the resist pattern is transferred to the inorganic film and the substrate by dry etching, whereby a desired patterned substrate can be obtained (see Japanese Unexamined Patent Application, Publication Nos. 2001-284209 and 2008-39811). The inorganic film-forming composition is required to be able to provide an inorganic film that exhibits superior etching selectivity with respect to a resist underlayer film or the like. To meet this demand, a silicon atom-containing compound (see Japanese Unexamined Patent Application, Publication No. 2010-85912), a metal atom-containing compound having a metalloxane skeleton (see Japanese Unexamined Patent Application (Translation of PCT Application), Publication No. 2005-537502), and the like have been developed.

### SUMMARY OF THE INVENTION

According to one aspect of the present invention, a composition for film formation includes a hydrolysis compound and a solvent composition. The hydrolysis compound is a hydrolysis product of a metal compound including a hydrolyzable group, a hydrolytic condensation product of the metal compound, a condensation product of the metal compound and a compound represented by formula (1), or a combination thereof.

R¹X¹)ₙ (1)

R¹ represents an organic group having a valency of n; X¹ represents —OH, —COOH, —NCO or —NHR^{a}; R^{a} represents a hydrogen atom or a monovalent organic group; n is an integer of 2 to 4; and a plurality of X¹s are identical or different. The metal compound cincludes a metal element from group 3, 4, 5, 6, 7, 8, 9, 10, 11, 12 or 13, or a combination thereof. The solvent composition includes an alcohol organic solvent, and a non-alcohol organic solvent that does not include an alcoholic hydroxyl group and that includes a group including a hetero atom. A content of the alcohol organic solvent with respect to a mass of the solvent composition is no less than 1% by mass and no greater than 50% by mass. A content of the non-alcohol organic solvent with respect to the mass of the solvent composition is no less than 50% by mass and no greater than 99% by mass.

According to another aspect of the present invention, a pattern-forming method includes applying the composition directly or indirectly on a front face of a substrate to provide an inorganic film. A resist pattern is formed directly or indirectly on a front face of the inorganic film. A pattern is formed on the substrate by a dry etching using the resist pattern as a mask.

### DESCRIPTION OF THE EMBODIMENTS

According to an embodiment of the present invention, a composition for film formation contains: a hydrolysis compound (hereinafter, may be also referred to as “(A) compound” or “compound (A)”) which is a hydrolysis product of a metal compound including a hydrolyzable group (hereinafter, may be also referred to as “metal compound (a)”), a hydrolytic condensation product of the metal compound including a hydrolyzable group, a condensation product of the metal compound including a hydrolyzable group and a compound represented by the following formula (1) (hereinafter, may be also referred to as “compound (i)”):

R¹X¹)ₙ (1)

wherein in the formula (1), R¹ represents an organic group having a valency of n; X¹ represents —OH, —COOH, —NCO or —NHR^{a}; R^{a} represents a hydrogen atom or a monovalent organic group; n is an integer of 2 to 4; and a plurality of X¹s are identical or different, or a combination thereof; and a solvent composition (hereinafter, may be also referred to as “(B) solvent composition” or “solvent composition (B)”), wherein the metal compound includes a metal element from group 3, 4, 5, 6, 7, 8, 9, 10, 11, 12 or 13, or a combination thereof, wherein the solvent composition (B) includes an alcohol organic solvent (hereinafter, may be also referred to as “(B1) alcohol solvent” or “alcohol solvent (B1)”), and a non-alcohol organic solvent that does not include an alcoholic hydroxyl group and includes a group containing a hetero atom (hereinafter, may be also referred to as “(B2) non-alcohol solvent” or “non-alcohol solvent (B2)”), wherein the content of the alcohol organic solvent with respect to the mass of the solvent composition is no less than 1% by mass and no greater than 50% by mass, and wherein the content of the non-alcohol organic solvent with respect to the mass of the solvent composition is no less than 50% by mass and no greater than 99% by mass.

According to another embodiment of the present invention, a pattern-forming method includes: providing an inorganic film directly or indirectly on a front face of a substrate using the composition for film formation according to the embodiment of the present invention; forming a resist pattern directly or indirectly on a front face of the inorganic film; and forming a pattern on the substrate by one or multiple dry etching using the resist pattern as a mask.

The term “hydrolyzable group” as referred to herein means a group that can be replaced with a hydroxy group through a reaction with water. Moreover, the term “metal compound including a hydrolyzable group” as referred to typically means a metal compound including a group that can be hydrolyzed by heating thereof in a temperature range of from room temperature (for example, 25° C.) to about 100° C. without any catalyst in the presence of an excess of water and can yield a hydroxy group. The “group containing a hetero atom” means groups having a hetero atom having a valency of no less than 2 in the structure thereof.

According to the composition for film formation and the pattern-forming method, both superior storage stability and superior inhibitory ability of volatilization can be exhibited. In particular, in inorganic film-forming compositions that contain a compound including a transition metal in the skeleton thereof, the molecular weight of a resin contained in the composition tends to be decreased after storage for a long time period, unlike intensively-investigated silicon-containing film-forming compositions. Thus, a phenomenon occurs that the film thickness of the inorganic film provided using the composition after the storage is decreased as compared with the inorganic film provided using the composition before the storage. According to the composition for film formation and the pattern-forming method, such decrease in the thickness can be suppressed. Further, in a case where the transition metal is included in the skeleton, a disadvantage is likely to be raised that components of the inorganic film are likely to be volatilized from the coating film upon baking in the formation of the inorganic film, whereby the inside of a chamber is highly likely to be contaminated. According to the composition for film formation and the pattern-forming method, such volatilization can be suppressed, too. Therefore, these can be very suitably used in processes for manufacture of large-scale integrated circuits (LSIs), in particular in the formation of fine contact holes and the like, in which further progress of miniaturization is expected in the future. Hereinafter, embodiments of the present invention are explained in detail.

### Composition for Film Formation

A composition for film formation according to an embodiment of the present invention contains the compound (A) and the solvent composition (B). The solvent composition (B) contains the alcohol solvent (B1) and the non-alcohol solvent (B2). The content of the alcohol solvent (B1) with respect to the mass of the solvent composition (B) is no less than 1% by mass and no greater than 50% by mass, and the content of the non-alcohol solvent (B2) with respect to the mass of the solvent composition (B) is no less than 50% by mass and no greater than 99% by mass. Due to having the constitution, the composition for film formation is superior in storage stability and inhibitory ability of volatilization. Although not necessarily clarified, the reason for achieving the effects described above resulting from the composition for film formation having the aforementioned constitution is presumed to be as in the following. Specifically, the alcohol solvent (B1) having superior solubilizing ability would inhibit the condensation of the compound (A), and also cleave the molecular chain of the compound (A), leading to a decrease of the molecular weight. The non-alcohol solvent (B2) would inhibit the cleavage of the molecular chain, whereby the decrease of the molecular weight of the compound (A) would be inhibited, and consequently the composition for film formation would exhibit superior storage stability and inhibitory ability of volatilization.

Moreover, the composition for film formation may contain an optional component such as a crosslinking accelerator, within a range not leading to impairment of the effects of the present invention. Hereinafter, each component is explained.

### (A) Compound

The compound (A) is a hydrolysis compound which is a hydrolysis product of the metal compound (a), a hydrolytic condensation product of the metal compound (a), a condensation product of the metal compound (a) and the compound (i), or a combination thereof, wherein the metal compound (a) includes a metal element from group 3, 4, 5, 6, 7, 8, 9, 10, 11, 12 or 13 (hereinafter, may be also referred to as “specific metal element”), or a combination thereof. Due to containing the compound (A), the composition for film formation enables an inorganic film that is superior in organic solvent resistance and etching resistance to be formed.

Further, the compound (A) may contain a metal element other than the specific metal element, and a compound other than the hydrolysis product of the metal compound (a) and the like in a small amount not leading to impairment of the effects of the present invention. Furthermore, the hydrolysis product of the metal compound (a) may include an unhydrolyzed hydrolyzable group.

Metal Compound Including Hydrolyzable Group

The metal compound (a) includes a hydrolyzable group, and includes the specific metal element. Due to the metal compound (a) including the specific metal element, the inorganic film formed from the composition for film formation is superior in organic solvent resistance and etching resistance. The metal compound (a) may include one, or two or more types of the specific metal element; and in light of an improvement of intra-plane uniformity of an etching rate in the inorganic film, the metal compound (a) preferably includes one type of the specific metal element. Moreover, due to the metal compound (a) including the hydrolyzable group, hydrolytic condensation can occur between the metal compound (a) molecules, or between the metal compound (a) and other compound. Consequently, the organic solvent resistance and the etching resistance of the inorganic film may be further improved.

Hydrolyzable Group

The hydrolyzable group can be replaced with a hydroxy group through a reaction with water. Examples of the hydrolyzable group include an alkoxy group, an aryloxy group, a halogen atom, an acetoxy group, an acyloxy group, an isocyanate group, and the like. Of these, an alkoxy group is preferred, a methoxy group, an ethoxy group, a propoxy group and a butoxy group are more preferred, and a propoxy group and a butoxy group are still more preferred.

Specific Metal Element

The specific metal element is a metal element from group 3, 4, 5, 6, 7, 8, 9, 10, 11, 12 or 13. The specific metal element is preferably titanium, aluminum, zirconium, hafnium, tungsten, molybdenum, tantalum or cobalt, and more preferably titanium, zirconium or tungsten. Due to the compound (A) including the specific metal element, the etching resistance of the inorganic film formed from the composition for film formation is further improved.

Compound (i)

The compound (i) is represented by the following formula (1).

R¹X¹)ₙ (1)

In the above formula (1), R¹ represents an organic group having a valency of n; X¹ represents —OH, —COOH, —NCO or —NHR^{a}; R^{a} represents a hydrogen atom or a monovalent organic group; n is an integer of 2 to 4; and a plurality of X¹s are identical or different.

The organic group having a valency of n which is represented by R′ is exemplified by: a hydrocarbon group having a valency of n; a group containing a hetero atom that has a valency of n and includes between two carbon atoms in the hydrocarbon group, a group having a hetero atom; a group having a valency of n which is obtained by substituting a part or all of hydrogen atoms included in the hydrocarbon group or the group containing a hetero atom with a substituent; and the like.

The hydrocarbon group having a valency of n is exemplified by groups obtained by removing n hydrogen atoms from a hydrocarbon such as a chain hydrocarbon having 1 to 30 carbon atoms, an alicyclic hydrocarbon having 3 to 30 carbon atoms and an aromatic hydrocarbon having 6 to 30 carbon atoms, and the like.

In these regards, the “hydrocarbon group” may be either a saturated hydrocarbon group or an unsaturated hydrocarbon group. The “chain hydrocarbon” as referred to means a hydrocarbon that is constituted with only a chain structure without including a cyclic structure, and the term “chain hydrocarbon” includes both linear hydrocarbons and branched hydrocarbons. The “alicyclic hydrocarbon” as referred to means a hydrocarbon that includes as a ring structure not an aromatic ring structure but only an alicyclic structure, and the term “alicyclic hydrocarbon” includes both monocyclic alicyclic hydrocarbons and polycyclic alicyclic hydrocarbons. However, it is not necessary for the alicyclic hydrocarbon to be constituted with only an alicyclic structure, and a part thereof may include a chain structure. The term “aromatic hydrocarbon” as referred to means a hydrocarbon that includes an aromatic ring structure as a ring structure. However, it is not necessary for the aromatic hydrocarbon to be constituted with only an aromatic ring structure, and a part thereof may include a chain structure or an alicyclic structure.

Examples of the chain hydrocarbon include: alkanes such as methane, ethane, propane and butane; alkenes such as ethene, propene, butene and pentene; alkynes such as ethyne, propyne, butyne and pentyne; and the like.

Examples of the alicyclic hydrocarbon include: cycloalkanes such as cyclopropane, cyclobutane, cyclopentane, cyclohexane, norbornane and adamantane; cycloalkenes such as cyclopropene, cyclobutene, cyclopentene, cyclohexene and norbornene; and the like.

The aromatic hydrocarbon is exemplified by: groups obtained by removing n hydrogen atoms from aromatic hydrocarbons such as aromatic hydrocarbons having 6 to 30 carbon atoms, e.g., arenes such as benzene, toluene, xylene, mesitylene, naphthalene, methylnaphthalene, dimethylnaphthalene and anthracene; and the like.

The group having a hetero atom is exemplified by groups that include at least one selected from the group consisting of an oxygen atom, a nitrogen atom, a silicon atom, a phosphorus atom and a sulfur atom, and the like, and examples thereof include —O—, —NH—, —CO—, —S—, a combination thereof, and the like. Of these, —O— is preferred.

Examples of the substituent include:
halogen atoms such as a fluorine atom, a chlorine atom, a bromine atom and an iodine atom;
alkoxy groups such as a methoxy group, an ethoxy group and a propoxy group;
alkoxycarbonyl groups such as a methoxycarbonyl group and an ethoxycarbonyl group;
alkoxycarbonyloxy groups such as a methoxycarbonyloxy group and an ethoxycarbonyloxy group;
acyl groups such as a formyl group, an acetyl group, a propionyl group, a butyryl group and a benzoyl group;
a cyano group, and a nitro group; and the like.

Preferably, n is 2 or 3, and more preferably 2.

The monovalent organic group which may be represented by R^{a} in —NHR^{a} is exemplified by: a monovalent hydrocarbon group having 1 to 20 carbon atoms; a group containing a hetero atom that includes between two carbon atoms in the hydrocarbon group, a group having a hetero atom; a group obtained by substituting a part or all of hydrogen atoms included in the hydrocarbon group and the group containing a hetero atom with a substituent; and the like. R^{a} represents preferably a monovalent hydrocarbon group, more preferably a monovalent chain hydrocarbon group, still more preferably an alkyl group, and particularly preferably a methyl group.

When n is 2, R¹ represents preferably a divalent chain hydrocarbon group, a divalent aromatic hydrocarbon group or a divalent group containing a hetero atom, more preferably an alkanediyl group, an alkenediyl group, an arenediyl group or an alkanediyloxyalkanediyl group, and still more preferably a 1,2-ethanediyl group, a 1,2-propanediyl group, a butanediyl group, a hexanediyl group, an ethenediyl group, a xylenediyl group or an ethanediyloxyethanediyl group.

Which n is 3, R¹ represents preferably a trivalent chain hydrocarbon group, more preferably an alkanetriyl group, and still more preferably a 1,2,3-propanetriyl group.

Which n is 4, R¹ represents preferably a tetravalent chain hydrocarbon group, more preferably alkanetetrayl group, and still more preferably a 1,2,3,4-butanetetrayl group.

Examples of the compound (i) include compounds represented by the following formulae (1-1) to (1-4) (hereinafter, may be also referred to as “compounds (i-1) to (i-4)”), and the like.

R¹OH)ₙ (1-1)

R¹COOH)ₙ (1-2)

R¹NCO)ₙ (1-3)

R¹NHR^{a})ₙ (1-4)

In the above formulae (1-1) to (1-4), R¹, R^{a} and n are as defined in the above formula (1).

Examples of the compound (i-1) in which n is 2 include:
alkylene glycols such as ethylene glycol, propylene glycol, butylene glycol and hexamethylene glycol;
dialkylene glycols such as diethylene glycol, dipropylene glycol, dibutylene glycol, triethylene glycol and tripropylene glycol;
cycloalkylene glycols such as cyclohexanediol, cyclohexanedimethanol, norbornanediol, norbornanedimethanol and adamantanediol;
aromatic ring-containing glycols such as 1,4-benzenedimethanol and 2,6-naphthalenedimethanol;
divalent phenols such as catechol, resorcinol and hydroquinone; and the like.

Examples of the compound (i-1) in which n is 3 include:
alkanetriols such as glycerin and 1,2,4-butanetriol;
cycloalkanetriols such as 1,2,4-cyclohexanetriol and 1,2,4-cyclohexanetrimethanol;
aromatic ring-containing glycols such as 1,2,4-benzenetrimethanol and 2,3,6-naphthalenetrimethanol;
trivalent phenols such as pyrogallol and 2,3,6-naphthalenetriol; and the like.

Examples of the compound (i-1) in which n is 4 include:
alkanetetraols such as erythritol and pentaerythritol;
cycloalkanetetraols such as 1,2,4,5-cyclohexanetetraol;
aromatic ring-containing tetraols such as 1,2,4,5-benzenetetramethanol;
tetravalent phenols such as 1,2,4,5-benzenetetraol; and the like.

As the compound (i-1), the compound (i-1) in which n is 2 or 3 is preferred, alkylene glycols, dialkylene glycols and alkanetriols are more preferred, and propylene glycol, diethylene glycol and glycerin are still more preferred.

Examples of the compound (i-2) in which n is 2 include:
chain saturated dicarboxylic acids such as oxalic acid, malonic acid, succinic acid, glutaric acid and adipic acid;
chain unsaturated dicarboxylic acids such as maleic acid and fumaric acid;
alicyclic dicarboxylic acids such as 1,4-cyclohexanedicarboxylic acid, norbornanedicarboxylic acid and adamantanedicarboxylic acid;
aromatic dicarboxylic acids such as phthalic acid, terephthalic acid, 2,6-naphthalenedicarboxylic acid and 2,7-naphthalenedicarboxylic acid; and the like.

Examples of the compound (i-2) in which n is 3 include:
chain saturated tricarboxylic acids such as 1,2,3-propanetricarboxylic acid;
chain unsaturated tricarboxylic acids such as 1,2,3-propenetricarboxylic acid;
alicyclic tricarboxylic acids such as 1,2,4-cyclohexanetricarboxylic acid;
aromatic tricarboxylic acids such as trimellitic acid and 2,3,7-naphthalenetricarboxylic acid; and the like.

Examples of the compound (i-2) in which n is 4 include:
chain saturated tetracarboxylic acids such as 1,2,3,4-butanetetracarboxylic acid;
chain unsaturated tetracarboxylic acids such as 1,2,3,4-butadienetetracarboxylic acid;
alicyclic tetracarboxylic acids such as 1,2,5,6-cyclohexanetetracarboxylic acid and 2,3,5,6-norbornanetetracarboxylic acid;
aromatic tetracarboxylic acids such as pyromellitic acid and 2,3,6,7-naphthalenetetracarboxylic acid; and the like.

Of these, as the compound (i-2), the compound (i-2) in which n is 2 is preferred, chain saturated dicarboxylic acids and chain unsaturated dicarboxylic acids are more preferred, and maleic acid and succinic acid are still more preferred.

Examples of the compound (i-3) in which n is 2 include:
chain diisocyanates such as ethylene diisocyanate, trimethylene diisocyanate, tetramethylene diisocyanate and hexamethylene diisocyanate;
alicyclic diisocyanates such as 1,4-cyclohexane diisocyanate and isophorone diisocyanate;
aromatic diisocyanates such as tolylene diisocyanate, 1,4-benzene diisocyanate and 4,4′-diphenylmethane diisocyanate; and the like.

Examples of the compound (i-3) in which n is 3 include:
chain triisocyanates such as trimethylene triisocyanate;
alicyclic triisocyanates such as 1,2,4-cyclohexane triisocyanate;
aromatic triisocyanates such as 1,2,4-benzene triisocyanate; and the like.

Examples of the compound (i-3) in which n is 4 include:
chain tetraisocyanates such as tetramethylene tetraisocyanate;
alicyclic tetraisocyanates such as 1,2,4,5-cyclohexane tetraisocyanate;
aromatic tetraisocyanates such as 1,2,4,5-benzene tetraisocyanate; and the like.

Of these, as the compound (i-3), the compound (i-3) in which n is 2 is preferred, chain diisocyanates are more preferred, and hexamethylene diisocyanate is still more preferred.

Examples of the compound (i-4) in which n is 2 include:
chain diamines such as ethylenediamine, N-methylethylenediamine, N,N′-dimethylethylenediamine, trimethylenediamine, N,N′-dimethyltrimethylenediamine, tetramethylenediamine and N,N′-dimethyltetramethylenediamine;
alicyclic diamines such as 1,4-cyclohexanediamine and 1,4-di(aminomethyl)cyclohexane;
aromatic diamines such as 1,4-diaminobenzene and 4,4′-diaminodiphenylmethane; and the like.

Examples of the compound (i-4) in which n is 3 include:
chain triamines such as triaminopropane and N,N′,N″-trimethyltriaminopropane;
alicyclic triamines such as 1,2,4-triaminocyclohexane;
aromatic triamines such as 1,2,4-triaminobenzene; and the like.

Examples of the compound (i-4) in which n is 4 include:
chain tetraamines such as tetraaminobutane;
alicyclic tetraamines such as 1,2,4,5-tetraaminocyclohexane and 2,3,5,6-tetraaminonorbornane;
aromatic tetraamines such as 1,2,4,5-tetraaminobenzene; and the like.

Of these, as the compound (i-4), the compound (i-4) in which n is 2 is preferred, chain diamines are more preferred, and N,N′-dimethylethylenediamine is still more preferred.

Moreover, the metal compound (a) is preferably a compound represented by the following formula (2).

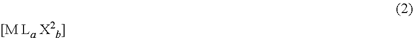

In the above formula (2), M represents a metal element from group 3, 4, 5, 6, 7, 8, 9, 10, 11, 12 or 13, or a combination thereof; L represents a ligand; a is an integer of 0 to 3, wherein in a case where a is no less than 2, a plurality of Ls are identical or different; X² represents the hydrolyzable group; b is an integer of 2 to 6; a plurality of X²s are identical or different; and a sum of twice a number a and a number b is no greater than 6.

The metal element represented by M is the above-specified metal element. M represents preferably titanium, aluminum, zirconium, hafnium, tungsten, molybdenum, tantalum or cobalt, and more preferably titanium, zirconium or tungsten.

The ligand represented by L is exemplified by a monodentate ligand and a polydentate ligand.

Examples of the monodentate ligand include a hydroxo ligand, carboxy ligands, amido ligands, and the like.

Examples of the amido ligand include an unsubstituted amido ligand (NH₂), methylamido ligand (NHMe), dimethylamido ligand (NMe₂), diethylamido ligand (NEt₂), dipropylamido ligand (NPr₂), and the like.

The polydentate ligand is exemplified by a hydroxy acid ester, a β-diketone, a β-keto ester, a β-dicarboxylic acid ester, a hydrocarbon having a π bond, a carboxylate anion, ammonia, and the like.

Examples of the hydroxy acid ester include glycolic acid esters, lactic acid esters, 2-hydroxycyclohexane-1-carboxylic acid esters, salicylic acid esters, and the like.

Examples of the β-diketone include acetylacetone, methylacetylacetone, ethylacetylacetone, 2,4-pentanedione, 3-methyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:
chain olefins such as ethylene and propylene;
cyclic olefins such as cyclopentene, cyclohexene and norbornene;
chain dienes such as butadiene and isoprene;
cyclic dienes such as cyclopentadiene, methylcyclopentadiene, pentamethylcyclopentadiene, cyclohexadiene and norbornadiene;
aromatic hydrocarbons such as benzene, toluene, xylene, hexamethylbenzene, naphthalene and indene; and the like.

In light of the stability of the compound (A), the ligand is preferably a polydentate ligand, more preferably a lactic acid ester, acetylacetone, an acetoacetic acid ester, a malonic acid diester, a cyclic diene and a carboxylate anion, and still more preferably ethyl lactate, 2,4-pentanedione, ethyl acetoacetate, diethyl malonate, cyclopentadiene and a stearic acid ester.

Preferably a is an integer of 0 to 2, and more preferably 0 or 1.

X² represents preferably an alkoxy group, more preferably a methoxy group, an ethoxy group, a propoxy group or a butoxy group, and still more preferably a propoxy group or a butoxy group.

Preferably b is an integer of 2 to 4, and more preferably 2 or 3, and still more preferably 2.

Examples of the metal compound (a) include:
metal compounds including four hydrolyzable groups such as tetra-i-propoxytitanium, tetra-n-butoxytitanium, tetraethoxytitanium, tetramethoxytitanium, tetra-i-propoxyzirconium, tetra-n-butoxyzirconium, tetraethoxyzirconium and tetramethoxyzirconium;

metal compounds including three hydrolyzable groups such as methyltrimethoxytitanium, methyltriethoxytitanium, methyltri-i-propoxytitanium, methyltributoxyzirconium, ethyltrimethoxyzirconium, ethyltriethoxyzirconium, ethyltri-i-propoxyzirconium, ethyltributoxyzirconium, butyltrimethoxytitanium, phenyltrimethoxytitanium, naphthyltrimethoxytitanium, phenyltriethoxytitanium, naphthyltriethoxytitanium, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, and titanium tributoxymonostearate;
metal compounds including two hydrolyzable groups such as dimethyldimethoxytitanium, diphenyldimethoxytitanium, dibutyldimethoxyzirconium, diisopropoxybisacetylacetonate, di-n-butoxybis(acetylacetonato)titanium, and di-n-butoxybis(acetylacetonato)zirconium;
metal compounds including one hydrolyzable group such as trimethylmethoxytitanium, triphenylmethoxytitanium, tributylmethoxytitanium, tri(3-methacryloxypropyl)methoxyzirconium, and tri(3-acryloxypropyl)methoxyzirconium; and the like.

As the metal compound (a), metal compounds including 2 to 4 hydrolyzable groups are preferred, and titanium tetraisopropoxide, titanium tetra-n-butoxide, titanium tributoxymonostearate, titanium diisopropoxybisacetylacetonate, and triethoxymonoacetylacetonatozirconium are more preferred.

The hydrolytic condensation reaction of the metal compound (a) or the like may be carried out, for example, in a water-containing solvent. The lower limit of the amount of water with respect to the compound in the hydrolytic condensation reaction is preferably an equimolar amount. On the other hand, the upper limit of the amount of water is preferably 20 times molar amount, and more preferably 15 times molar amount. In addition, the hydrolytic condensation reaction may be carried out in the presence of an acid and/or an acid anhydride such as maleic anhydride in addition to water, in light of the acceleration of the hydrolysis reaction and the condensation reaction.

The solvent for use in the reaction (hereinafter, may be also referred to as “reaction solvent”) is not particularly limited, and solvents similar to those exemplified in connection with the solvent composition (B) described later may be used. Of these, alcohol organic solvents, ether organic solvents, ester organic solvents and hydrocarbon organic solvents are preferred, monovalent aliphatic alcohols, alkylene glycol monoalkyl ethers, hydroxy acid esters, alkylene glycol monoalkyl ether carboxylic acid esters, lactones, cyclic ethers and aromatic hydrocarbons are more preferred, monovalent aliphatic alcohols having 2 or more carbon atoms, alkylene glycol monoalkyl ethers having 6 or more carbon atoms, hydroxy acid esters having 4 or more carbon atoms, alkylene glycol monoalkyl ether carboxylic acid esters having 6 or more carbon atoms, lactones having 4 or more carbon atoms, cyclic ethers having 4 or more carbon atoms, and aromatic hydrocarbons having 7 or more carbon atoms are still more preferred, and methanol, ethanol, isopropanol, n-butanol, propylene glycol monomethyl ether, propylene glycol monoethyl ether, propylene glycol monopropyl ether, ethyl lactate, propylene glycol monomethyl ether acetate, γ-butyrolactone, tetrahydrofuran and toluene are particularly preferred.

After the completion of the reaction, the reaction solvent may be directly used as the solvent composition (B) in the composition for film formation without removal thereof. In this procedure, a solvent composition which contains the alcohol solvent (B1) and the non-alcohol solvent (B2) in a content of no less than 1% by mass and no greater than 50% by mass, and no less than 50% by mass and no greater than 99% by mass, respectively, may be used as the reaction solvent. Alternatively, the alcohol solvent (B1) or the like may be added after the completion of the reaction to prepare the composition for film formation such that the content of the alcohol solvent (B1) and the content of the non-alcohol solvent (B2) in the solvent composition (B) each fall within the above-specified range.

The lower limit of the temperature of the reaction is preferably 0° C., and more preferably 10° C. On the other hand, the upper limit of the temperature of the reaction is preferably 150° C., and more preferably 120° C. The lower limit of the time period of the reaction is preferably 30 min, more preferably 1 hour, and still more preferably 2 hrs. On the other hand, the upper limit of the time period of the reaction is preferably 24 hrs, more preferably 20 hrs, and still more preferably 15 hrs.

Alternatively, the polydentate ligand such as ethyl lactate may be added to the reaction liquid obtained in the hydrolytic condensation reaction.

Furthermore, the compound (A) may include a compound synthesized by a procedure other than the procedure involving subjecting the compound described above to the hydrolytic condensation. The procedure other than the hydrolytic condensation is exemplified by: a procedure that involves allowing a metal compound including an alkoxy ligand, a metal compound including a halogen ligand, or the like to react with a ligand or the like in a water-containing solvent; a procedure that involves allowing a complex having the specific metal element and an oxygen atom bonding to the specific metal element to react with a ligand or the like in a solvent; and the like.

The lower limit of the absolute molecular weight of the compound (A) as determined by static light scattering is preferably 6,000, more preferably 8,000, and still more preferably 9,000. The upper limit of the absolute molecular weight is preferably 50,000, more preferably 45,000, and still more preferably 40,000. When the absolute molecular weight of the compound (A) falls within the aforementioned range, the composition for film formation may achieve both the storage stability and the inhibitory ability of volatilization at a higher level. When the absolute molecular weight of the compound (A) is less than the lower limit, the inhibitory ability of volatilization of the composition for film formation may be deteriorated. To the contrary, when the absolute molecular weight of the compound (A) is greater than the upper limit, the storage stability of the composition for film formation may be deteriorated.

The absolute molecular weight of the compound (A) as determined by the static light scattering is determined using the following apparatus under the following condition. It is to be noted that a procedure for the determination is exemplified by: a procedure that involves charging a sample solution into a quartz cell, followed by placing the quartz cell in an apparatus, as is the case of using the apparatus described below; a procedure that involves using a multiangle laser light scattering detector (MALLS), in which a sample solution is injected into a flow cell; and the like, and any of these procedures may be used to determine the absolute molecular weight of the compound (A) under the condition involving the following and using:
apparatus: light scattering measurement apparatus (“ALV-5000”, available from ALV-GmbH, Germany);
measurement concentration: 4 levels of 2.5% by mass, 5.0% by mass, 7.5% by mass, and 10.0% by mass;
standard liquid: toluene; and
measurement temperature: 23° C.

The refractive index and the density of a solution which are necessary for the calculation of the absolute molecular weight are determined using the following apparatuses:
apparatus for determination of the refractive index of a solution: refractometer (“RA-500” available from Kyoto Electronics Manufacturing Co., Ltd.);
apparatus for determination of the density of a solution: density/specific gravity meter (“DA-100” available from Kyoto Electronics Manufacturing Co., Ltd.).

### (B) Solvent Composition

The solvent composition (B) includes the alcohol solvent (B1) and the non-alcohol solvent (B2). In addition, the content of the alcohol organic solvent (B1) with respect to the mass of the solvent composition (B) is no less than 1% by mass and no greater than 50% by mass, and the content of the non-alcohol solvent (B2) with respect to the mass of the solvent composition (B) is no less than 50% by mass and no greater than 99% by mass. Due to the solvent composition (B) including the alcohol solvent (B1) and the non-alcohol solvent (B2) at the above-specified proportions, the composition for film formation is superior in storage stability and inhibitory ability of volatilization. The alcohol solvent (B1) and the non-alcohol solvent (B2) each may include only a single type of the solvent, or may be a mixed solvent of two or more types thereof. The solvent used in the reaction for the synthesis of the compound (A) may be directly used as the solvent composition (B) without removal thereof.

The alcohol solvent (B1) is exemplified by a monovalent aliphatic alcohol, a monovalent alicyclic alcohol, an aromatic alcohol, a monovalent ether group- or keto group-containing alcohol, a polyhydric alcohol, an alkylene glycol monoalkyl ether, an ether group-containing alkylene glycol monoalkyl ether, and the like.

Examples of the monovalent aliphatic alcohol include methanol, ethanol, n-propanol, iso-propanol, n-butanol, iso-butanol, sec-butanol, tert-butanol, n-pentanol, iso-amyl alcohol, 2-methylbutanol, sec-pentanol, tert-pentanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, and the like.

Examples of the monovalent alicyclic alcohol include cyclohexanol, methylcyclohexanol, 3,3,5-trimethylcyclohexanol, and the like.

Examples of the aromatic alcohol include benzyl alcohol, phenethyl alcohol, and the like.

Examples of the monovalent ether group- or keto group-containing alcohol include 3-methoxybutanol, furfuryl alcohol, diacetone alcohol, and the like.

Examples of the polyhydric alcohol include ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and the like.

Examples of the alkylene glycol monoalkyl ether include ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, propylene glycol monomethyl ether, propylene glycol monoethyl ether, propylene glycol monopropyl ether, propylene glycol monobutyl ether, and the like.

Examples of the ether group-containing alkylene glycol monoalkyl ether include diethylene glycol monomethyl ether, diethylene glycol monoethyl ether, diethylene glycol monopropyl ether, diethylene glycol monobutyl ether, diethylene glycol monohexyl ether, dipropylene glycol monomethyl ether, dipropylene glycol monoethyl ether, dipropylene glycol monopropyl ether, and the like.

Of these, the alcohol solvent (B1) is preferably an alkylene glycol monoalkyl ether, more preferably propylene glycol monoalkyl ether, still more preferably propylene glycol monoethyl ether, propylene glycol monomethyl ether, propylene glycol monopropyl ether, and particularly preferably propylene glycol monoethyl ether, in light of a further improvement of the storage stability and the inhibitory ability of volatilization.

The non-alcohol solvent (B2) is an organic solvent that does not include an alcoholic hydroxyl group and includes a group containing a hetero atom. The group containing a hetero atom may have either one, or two or more hetero atom(s) having a valency of no less than 2.

The hetero atom having a valency of no less than 2 which is included in the group containing a hetero atom is not particularly limited as long as the hetero atom has an atomic valence of no less than 2, and examples thereof include an oxygen atom, a nitrogen atom, a sulfur atom, a silicon atom, a phosphorus atom, a boron atom, and the like.

Examples of the group containing a hetero atom include:
groups obtained by combining two or more hetero atoms such as —SO—, —SO₂—, —SO₂O—, and —SO₃—;
groups obtained by combining at least one carbon atom(s) and at least one hetero atom(s) such as —CO—, —COO—, —COS—, —CONH—, —OCOO—, —OCOS—, —OCONH—, —SCONH—, —SCSNH—, and —SCSS—; and the like.

The group containing a hetero atom is preferably —CO—, —O—, or —NR—, wherein R represents a hydrogen atom or a hydrocarbon group having 1 to 10 carbon atoms. Due to the non-alcohol solvent (B2) including any of these groups containing a hetero atom, a degree of the increase or decrease of the molecular weight described above may be more effectively reduced, and consequently, the composition for film formation may be superior in storage stability and inhibitory ability of volatilization.

The hydrocarbon group having 1 to 10 carbon atoms which may be represented by R is exemplified by a chain hydrocarbon group, an alicyclic hydrocarbon group, an aromatic hydrocarbon group, and the like.

Examples of the chain hydrocarbon group include:
alkyl groups such as a methyl group, an ethyl group, a propyl group and a butyl group;
alkenyl groups such as an ethenyl group, a propenyl group and a butenyl group;
alkynyl groups such as an ethynyl group, a propynyl group and a butynyl group; and the like.

Examples of the alicyclic hydrocarbon group include:
cycloalkyl groups such as a cyclopropyl group, a cyclopentyl group, a cyclohexyl group, a norbornyl group and an adamantyl group;
cycloalkenyl groups such as a cyclopropenyl group, a cyclopentenyl group, a cyclohexenyl group and a norbornenyl group; and the like.

Examples of the aromatic hydrocarbon group include:
aryl groups such as a phenyl group, a tolyl group, a xylyl group, a naphthyl group and an anthryl group;
aralkyl groups such as a benzyl group, a phenethyl group and a naphthylmethyl group; and the like.

Moreover, the non-alcohol solvent (B2) is preferably an ester organic solvent, a ketone organic solvent, an amide organic solvent or an ether organic solvent.

The ester organic solvent is exemplified by a monocarboxylic acid ester, a dicarboxylic acid ester, a carboxylic acid ester of an alkylene glycol monoalkyl ether, a carboxylic acid ester of an ether group-containing alkylene glycol monoalkyl ether, a hydroxy acid ester, a lactone, a carbonate, and the like.

Examples of the monocarboxylic acid ester include methyl acetate, ethyl acetate, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, ethyl propionate, n-butyl propionate, iso-amyl propionate, methyl acetoacetate, ethyl acetoacetate, and the like.

Examples of the dicarboxylic acid ester include diethyl oxalate, di-n-butyl oxalate, diethyl malonate, dimethyl phthalate, diethyl phthalate, and the like.

Examples of the carboxylic acid ester of an alkylene glycol monoalkyl ether include ethylene glycol monomethyl ether acetate, ethylene glycol monoethyl ether acetate, ethylene glycol monopropyl ether acetate, propylene glycol monomethyl ether acetate, propylene glycol monoethyl ether acetate, propylene glycol monopropyl ether acetate, propylene glycol monobutyl ether acetate, propylene glycol monomethyl ether propionate, and the like.

Examples of the carboxylic acid ester of an ether group-containing alkylene glycol monoalkyl ether include diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, diethylene glycol monomethyl ether propionate, and the like.

Examples of the hydroxy acid ester include methyl glycolate, ethyl glycolate, methyl lactate, ethyl lactate, n-butyl lactate, n-amyl lactate, and the like.

Examples of the lactone include γ-butyrolactone, γ-valerolactone, and the like.

Examples of the carbonate include diethyl carbonate, propylene carbonate, and the like.

Examples of the ketone organic solvent include:
chain ketones such as acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, diiso-butyl ketone and trimethylnonanone;
cyclic ketones such as cyclopentanone, cyclohexanone, cycloheptanone, cyclooctanone and methylcyclohexanone;
aromatic ketones such as acetophenone and phenyl ethyl ketone;
γ-diketones such as acetonylacetone; and the like.

Examples of the amide organic solvent include:
chain amides such as N-methylformamide, N,N-dimethylformamide, N,N-diethylformamide, acetamide, N-methylacetamide, N,N-dimethylacetamide and N-methylpropionamide;
cyclic amides such as N-methylpyrrolidone and N,N′-dimethylimidazolidinone; and the like.

Examples of the ether organic solvent include:
dialiphatic ethers such as diethyl ether and dipropyl ether;
aromatic-aliphatic ethers such as anisole and phenyl ethyl ether;
diaromatic ethers such as diphenyl ether;
cyclic ethers such as tetrahydropyran, tetrahydropyran and dioxane; and the like.

Of these, the non-alcohol solvent (B2) is more preferably an ester organic solvent, still more preferably propylene glycol alkyl ether acetate, and particularly preferably propylene glycol monomethyl ether acetate, in light of a further improvement of the storage stability and the inhibitory ability of volatilization.

The lower limit of the content of the alcohol solvent (B1) with respect to the mass of the solvent composition (B) is 1% by mass, preferably 20% by mass, and more preferably 30% by mass. On the other hand, the upper limit of the content is 50% by mass.

The lower limit of the content of the non-alcohol solvent (B2) with respect to the mass of the solvent composition (B) is 50% by mass. On the other hand, the upper limit of the content is 99% by mass, preferably 80% by mass, and still more preferably 70% by mass.

When the content of the alcohol solvent (B1) and the content of the non-alcohol solvent (B2) each fall within the above range, a degree of the increase or decrease of the molecular weight of the compound (A) described above may be more effectively reduced, and consequently, the storage stability and the inhibitory ability of volatilization of the composition for film formation may be further improved.

Moreover, the solvent composition (B) may include other solvent such as water and a hydrocarbon solvent. However, a sum of the amounts of the alcohol solvent (B1), the non-alcohol solvent (B2) and the other solvent does not exceed 100% by mass. The upper limit of the content of the other solvent with respect to the mass of the solvent composition (B) is preferably 10%, more preferably 5%, and still more preferably 2%.

The lower limit of the content of the solvent composition (B) is a value that gives the content of the compound (A) in the composition for film formation of 0.1% by mass, preferably 0.5% by mass, more preferably 1% by mass, and still more preferably 2% by mass. On the other hand, the upper limit of the content of the solvent composition (B) is a value that gives the content of the compound (A) in the composition for film formation of 50% by mass, preferably 30% by mass, more preferably 15% by mass, and still more preferably 10% by mass. When the content of the compound (A) in the composition falls within the above range, the storage stability and the coating properties of the composition for film formation may be further improved.

Examples of the hydrocarbon solvent include:
aliphatic hydrocarbon solvents such as n-pentane, i-pentane, n-hexane, hexane, n-heptane, i-heptane, 2,2,4-trimethylpentane, n-octane, i-octane, cyclohexane and methylcyclohexane;
aromatic hydrocarbon solvents such as benzene, toluene, xylene, mesitylene, ethylbenzene, trimethylbenzene, methylethylbenzene, n-propylbenzene, i-propylbenzene, diethylbenzene, i-butylbenzene, triethylbenzene, di-i-propylbenzene and n-amylnaphthalene; and the like.

### Optional Component

The composition for film formation may further contain an optional component such as a crosslinking accelerator and a surfactant within a range not leading to impairment of the effects of the present invention.

Crosslinking Accelerator

The crosslinking accelerator generates an acid or a base by means of light or heat. When the composition for film formation further contains the crosslinking accelerator, organic solvent resistance and etching resistance is thereof can be improved. The crosslinking accelerator is exemplified by: an onium salt compound such as a sulfonium salt and an iodonium salt; N-sulfonyloxyimide compound; and the like. The crosslinking accelerator is preferably a thermal crosslinking accelerator that thermally generates an acid or a base, more preferably an onium salt compound, and still more preferably an iodonium salt or an ammonium salt.

The crosslinking accelerator may be used either alone, or two or more types thereof may be used in combination. The lower limit of the content of the crosslinking accelerator with respect to 100 parts by mass of the compound (A) is preferably 0 parts by mass, and more preferably 0.1 parts by mass. On the other hand, the upper limit of the content is preferably 10 parts by mass, and more preferably 5 parts by mass. When the content of the crosslinking accelerator falls within the above range, the organic solvent resistance and the etching resistance of the composition for film formation can be further improved.

Surfactant

The surfactant exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, and polyethylene glycol dilaurate and polyethylene glycol distearate; commercially available products such as KP341 (Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Tochem Products Co. Ltd.), Megaface F171 and Megaface F173 (each available from Dainippon Ink And Chemicals, Incorporated), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.); and the like.

The surfactant may be used either alone, or two or more types thereof may be used in combination. Moreover, the amount of the surfactant blended may be appropriately selected in accordance with the purpose of the blending.

### Preparation Method of Composition

The composition for film formation may be prepared, for example, by mixing the compound (A) and the solvent composition (B), as well as the other optional component such as the crosslinking accelerator as needed, at a certain ratio. Alternatively, the solvent used in the synthesis of the compound (A) may be directly used as the solvent composition (B) to prepare the composition, as described above. The composition for film formation may be prepared in normal use by further adding a solvent to adjust the concentration thereof, and thereafter filtering the solution through a filter having a pore size of, for example, about 0.2 μm.

### Pattern-Forming Method

A pattern-forming method according to another embodiment of the present invention includes: providing an inorganic film directly or indirectly on a front face of a substrate using the composition for film formation according to the embodiment of the present invention (hereinafter, may be also referred to as “inorganic film-providing step”); forming a resist pattern directly or indirectly on a front face of the inorganic film (hereinafter, may be also referred to as “resist pattern-forming step”); and forming a pattern on the substrate by one or multiple dry etching using the resist pattern as a mask (hereinafter, may be also referred to as “substrate pattern-forming step”).

According to the pattern-forming method, since the composition described above is used, superior storage stability and inhibitory ability of volatilization can be exhibited. Accordingly, the control of the thickness of the inorganic film may be facilitated, and additionally the contamination of the inside of a chamber can be reduced. Therefore, a pattern can be formed more easily.

In addition, it is preferred that the pattern-forming method further includes after the inorganic film-providing step, overlaying an antireflective film directly or indirectly on the front face of the inorganic film (hereinafter, may be also referred to as “antireflective film-overlaying step”), and it is also preferred that the pattern-forming method further includes before the inorganic film-providing step, providing a resist underlayer film directly or indirectly on the front face of the substrate (hereinafter, may be also referred to as “resist underlayer film-providing step”).

Hereinafter, each step is explained.

### Resist Underlayer Film-Providing Step

In this step, a resist underlayer film which is an organic film is provided directly or indirectly on a front face of the substrate using a resist underlayer film-forming composition. Conventionally well-known resist underlayer film-forming compositions may be used as the resist underlayer film-forming composition, and examples thereof include NFC HM8005 (available from JSR Corporation), and the like. The resist underlayer film may be provided by applying the resist underlayer film-forming composition directly or indirectly to the front face of the substrate to provide a coating film, and subjecting the coating film to a heat treatment, or a combination of irradiation with ultraviolet light and a heat treatment to allow curing thereof. The procedure for applying the resist underlayer film-forming composition is exemplified by a spin coating procedure, a roll coating procedure, a dip coating procedure, and the like. Moreover, the lower limit of the temperature of the heat treatment is typically 150° C., and preferably 180° C. On the other hand, the upper limit of the aforementioned temperature is typically 500° C., and preferably 350° C. The lower limit of the time period of the heat treatment is typically 30 sec, and preferably 45 sec. On the other hand, the upper limit of the aforementioned time period is typically 1,200 sec, and preferably 600 sec. The condition of the irradiation with ultraviolet light may be appropriately selected in accordance with the formulation of the resist underlayer film-forming composition, and the like. The film thickness of the resist underlayer film provided is typically no less than 50 nm and no greater than 500 nm.

Furthermore, other underlayer film distinct from the resist underlayer film described above may be provided directly or indirectly on the front face of the substrate. This other underlayer film is a film to which a reflection-preventing function, coating film flatness, superior etching resistance against fluorine-based gases such as CF₄, and/or the like are imparted. Commercially available products such as e.g., NFC HM8005 (available from JSR Corporation) may be used as the other underlayer film.

### Inorganic Film-Providing Step

In this step, an inorganic film is provided directly or indirectly on the front face of the substrate using the composition for film formation. In a case where the resist underlayer film-providing step is not involved, the inorganic film is provided on the front face of the substrate, whereas in a case where the resist underlayer film-providing step is involved, the inorganic film is provided on a front face of the resist underlayer film. Examples of the substrate include insulating films such as silicon oxide, silicon nitride, silicon nitride oxide and polysiloxane, as well as interlayer insulating films such as wafers covered with a low-dielectric insulating film such as Black Diamond™ (available from AMAT), SiLK™ (available from Dow Chemical), and LKD5109 (available from JSR Corporation), which are commercially available products. Moreover, a substrate patterned so as to have wiring grooves (trench), plug grooves (vias) or the like may be used as the substrate. The inorganic film may be formed by applying the composition for film formation directly or indirectly to the front face of the substrate to provide a coating film, and subjecting the coating film to a heat treatment, or a combination of irradiation with ultraviolet light and a heat treatment to allow curing thereof. The procedure for applying the composition for film formation is exemplified by a spin coating procedure, a roll coating procedure, a dip coating procedure, and the like. Moreover, the lower limit of the temperature of the heat treatment is typically 150° C., and preferably 180° C. On the other hand, the upper limit of the aforementioned temperature is typically 500° C., and preferably 350° C. The lower limit of the time period of the heat treatment is typically 30 sec, and preferably 45 sec. On the other hand, the upper limit of the aforementioned time period is typically 1,200 sec, and preferably 600 sec. The condition of the irradiation with ultraviolet light may be appropriately selected in accordance with the formulation of the composition for film formation, and the like. The film thickness of the inorganic film formed is typically no less than 5 nm and no greater than 50 nm.

### Antireflective Film-Overlaying Step

In this step, an antireflective film is overlaid directly or indirectly on the front face of the inorganic film. Organic antireflective films or inorganic antireflective films disclosed in, for example, Japanese Examined Patent Application, Publication No. H6-12452 and Japanese Unexamined Patent Application, Publication No. S59-93448, and the like may be used as the antireflective film. When the antireflective film is thus further provided, the resist pattern formability can be further improved.

### Resist Pattern-Forming Step

In this step, a resist pattern is formed directly or indirectly on the front face of the provided inorganic film. In a case where the antireflective film-overlaying step is not involved, the resist pattern is formed on the front face of the inorganic film, whereas in a case where the antireflective film-overlaying step is involved, the resist pattern is formed on a front face of the antireflective film. The procedure for forming the resist pattern is exemplified by a procedure involving use of a resist composition, and the like. In the procedure involving use of a resist composition, the resist pattern-forming step includes: providing a resist film directly or indirectly on the front face of the inorganic film using the resist composition (hereinafter, may be also referred to as “resist film-providing step”); exposing the resist film (hereinafter, may be also referred to as “exposure step”); and developing the resist film exposed (hereinafter, may be also referred to as “development step”).

Hereinafter, each step is explained.

Resist Film-Providing Step

In this step, a resist film is formed by applying a resist composition directly or indirectly to the front face of the inorganic film to provide a coating film, and subjecting the coating film to prebaking (PB) or the like to allow a solvent in the coating film to be volatilized. The resist composition is exemplified by: a chemical amplification resist composition that contains a polymer including an acid-labile group, and a radiation-sensitive acid generating agent; a positive type resist composition that contains an alkali-soluble resin and a quinone diazide photosensitizing agent; a negative type resist composition that contains an alkali-soluble resin and a crosslinking agent; and the like. Commercially available resist compositions may be used as such a resist composition.

The resist composition may be applied by, for example, a conventional method such as a spin coating procedure. It is to be noted that when the resist composition is applied, the amount of the resist composition applied is adjusted such that the resulting resist film has a desired film thickness.

The temperature of the PB may be appropriately adjusted in accordance with the type of the resist composition employed, and the like; however, the lower limit of the aforementioned temperature is preferably 30° C., and more preferably 50° C. On the other hand, the upper limit of the aforementioned temperature is preferably 200° C., and more preferably 150° C. The lower limit of the time period of the PB is typically 30 sec, and preferably 45 sec. On the other hand, the upper limit of the aforementioned time period is typically 200 sec, and preferably 120 sec. The lower limit of the film thickness of the provided resist film is typically 1 nm, and preferably 10 nm. On the other hand, the upper limit of the film thickness is typically 500 nm, and preferably 300 nm. It is to be noted that other film may be further provided directly or indirectly on a front face of the resist film.

Exposure Step

In this step, the provided resist film is exposed. This exposure is typically executed by selectively irradiating the resist film with a radioactive ray through a photomask. The radioactive ray employed in the exposure may be appropriately selected in accordance with the type of acid generating agent used in the resist composition, from e.g., electromagnetic waves such as visible light rays, ultraviolet rays, far ultraviolet rays, X-rays and γ-rays; particle rays such as electron beams, molecular beams and ion beams; and the like. However, far ultraviolet rays are preferred, a KrF excimer laser beam (248 nm), an ArF excimer laser beam (193 nm), an F₂ excimer laser beam (wavelength: 157 nm), a Kr₂ excimer laser beam (wavelength: 147 nm), an ArKr excimer laser beam (wavelength: 134 nm), and extreme-ultraviolet rays (wavelength: 13 nm, etc.) are more preferred. The exposure may also be executed through a liquid immersion medium. In this case, a liquid immersion upper layer film may be provided directly or indirectly on the front face of the resist film using a composition for forming a liquid immersion upper layer film.

In order to improve the resolution, the pattern profile, the developability, etc. of the resist film, post-baking is preferably executed after the exposure. The temperature of the post-baking may be appropriately adjusted in accordance with the type of the resist composition employed and the like; however, the lower limit of the temperature is preferably 50° C., and more preferably 70° C. On the other hand, the upper limit of the aforementioned temperature is preferably 180° C., and more preferably 150° C. The lower limit of the time period of post-baking is typically 30 sec, and preferably 45 sec. On the other hand, the upper limit of the time period is typically 200 sec, and preferably 120 sec.

Development Step

In this step, the resist film exposed is developed. The developer solution which may be used in the development may be appropriately selected in accordance with the type of the resist composition employed. In the case of the chemical amplification resist composition and the positive type resist composition, aqueous alkaline solutions may be used as the developer solution. Thus, a positive type resist pattern can be formed by using an aqueous alkaline solution.

The aqueous alkaline solution is exemplified by an aqueous alkaline solution of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, 1,5-diazabicyclo[4.3.0]-5-nonene or the like. Of these, an aqueous TMAH solution is preferred. An appropriate amount of a water soluble organic solvent, for example, an alcohol such as methanol and ethanol and/or a surfactant may be added to these aqueous alkaline solutions.

Moreover, in the case of the chemical amplification resist composition, an organic solvent may be used as the developer solution. Thus, a negative type resist pattern can be formed by using an organic solvent. Examples of the organic solvent include solvents similar to those exemplified in connection with the solvent composition (B) in the composition for film formation, and the like. Of these, the ester solvent is preferred, and butyl acetate is more preferred.

In addition, in the case of the chemical amplification resist composition and the negative type resist composition, an aqueous solution of the following alkali may be used as the developer solution, for example:
inorganic alkalis such as sodium hydroxide, potassium hydroxide, sodium carbonate, sodium silicate, sodium metasilicate and aqueous ammonia;
primary amines such as ethylamine and n-propylamine;
secondary amines such as diethylamine and di-n-butylamine;
tertiary amines such as triethylamine and methyldiethylamine;
alcoholamines such as dimethylethanolamine and triethanolamine;
quaternary ammonium salts such as tetramethylammonium hydroxide, tetraethylammonium hydroxide and choline;
cyclic amines such as pyrrole and piperidine; and the like. A negative type resist pattern can be formed by using these solutions as the developer solution.

In addition, the resist pattern may be formed by a procedure involving nanoimprint lithography, a procedure involving the use of a directed self-assembling composition, or the like.

In a case where the resist pattern is foil led by the procedure involving nanoimprint lithography, the resist pattern-forming method includes: providing a pattern formation layer on the inorganic film using a radiation-sensitive composition for nanoimprinting; subjecting the surface of a mold having a reversal pattern on the surface thereof to a hydrophobilization treatment; pressure welding the surface of the mold subjected to the hydrophobilization treatment onto the pattern formation layer; exposing the pattern formation layer while pressure welding the mold; and releasing the mold from the pattern formation layer exposed.

In a case where the resist pattern is formed by the procedure involving the use of the directed self-assembling composition, the resist pattern-forming method includes: applying the directed self-assembling composition directly or indirectly to the front face of the inorganic film, followed by annealing or the like to form a directed self-assembling film; and removing a part of a plurality of phases of the directed self-assembling film. The “directed self-assembling composition” as referred to herein means a composition that forms a phase separation structure through directed self-assembly, and is exemplified by a composition that contains a block copolymer, and the like.

### Substrate Pattern-Forming Step

In this step, a pattern is formed on the substrate by one or multiple dry etching using the resist pattern as a mask. It is to be noted that in a case where the resist underlayer film is provided, the inorganic film, the resist underlayer film and the substrate are sequentially dry etched using the resist pattern as a mask to form the pattern. The dry etching may be executed using a well-known dry etching apparatus. In addition, examples of the gas which may be used as a source gas in the dry etching include: oxygen atom-containing gases such as O₂, CO and CO₂; inert gases such as He, N₂ and Ar; chlorine-based gases such as Cl₂ and BCl₃; fluorine-based gases such as CHF₃ and CF₄; other gases such as H₂ and NH₃, which may be selected depending on the elemental composition of the substance to be etched. It is to be noted that these gases may also be used in mixture.

### EXAMPLES

Hereinafter, the embodiment of the present invention will be explained in more detail by way of Examples, but the present invention is not in any way limited to these Examples. Measuring methods for physical properties in Examples are shown below.

### Absolute Molecular Weight of Compound (A)

The absolute molecular weight of the compound (A) was determined by a static light scattering method using a light scattering measurement apparatus (“ALV-5000”, available from ALV-GmbH, Germany) under the condition involving the following:
standard liquid: toluene; and
measurement temperature: 23° C.

It is to be noted that the following parameters necessary for the calculation of the absolute molecular weight were determined by using the following apparatuses:
refractive index of a solution: refractometer (“RA-500” available from Kyoto Electronics Manufacturing Co., Ltd.); and
density of a solution: density/specific gravity meter (“DA-100” available from Kyoto Electronics Manufacturing Co., Ltd.).

### Synthesis of Compound (A)

### Synthesis Example 1

To a mixed liquid of 100 g of methanol and 15 g of titanium tetra-n-butoxide was slowly added dropwise 1 g of ion exchanged water. After the mixture was stirred at room temperature for 120 min, the mixture was heated to 70° C. and stirred for 180 min. To this mixed liquid were added 9 g of acetylacetone and 150 g of propylene glycol-1-methyl ether, and the mixture was concentrated under a vacuum environment to obtain a solution of a compound (A-1) in propylene glycol-1-methyl ether. The concentration of the compound (A-1) in this solution was 12% by mass.

### Synthesis Example 2

To a mixed liquid of 100 g of n-butanol and 10 g of zirconium tributoxymonoacetylacetonate was slowly added dropwise 1 g of ion exchanged water. After the mixture was stirred at room temperature for 60 min, the mixture was heated to 50° C. and stirred for 120 min. The mixed liquid was concentrated under a vacuum environment to obtain a solution of a compound (A-2) in n-butanol. The concentration of the compound (A-2) in this solution was 10% by mass.

### Synthesis Example 3

To a mixed liquid of 100 g of isopropanol and 18 g of titanium diisopropoxybisacetylacetonate was slowly added dropwise 5.2 g of ion exchanged water. After the mixture was stirred at room temperature for 30 min, the mixture was heated to 60° C. and stirred for 240 min. To this mixed liquid was added 200 g of propylene glycol-1-methyl ether acetate, and the mixture was concentrated under a vacuum environment to obtain a solution of a compound (A-3) in propylene glycol-1-methyl ether acetate. The concentration of the compound (A-3) in this solution was 11% by mass.

### Synthesis Example 4

To a mixed liquid of 100 g of ethanol, 3 g of benzoylacetone and 0.9 g of ion exchanged water was slowly added dropwise 9 g of titanium tetraisopropoxide, and the mixture was stirred at room temperature for 90 min. After 1 g of tetraethoxysilane was slowly added dropwise to the mixed liquid, the mixture was heated to 70° C. and stirred for 120 min. To this mixed liquid were added 2.5 g of ethyl acetoacetate and 150 g of propylene glycol-1-ethyl ether, and the mixture was concentrated under a vacuum environment to obtain a solution of a compound (A-4) in propylene glycol-1-ethyl ether. The concentration of the compound (A-4) in this solution was 12% by mass.

### Synthesis Example 5

A mixed liquid of 100 g of 1-propanol, 9.8 g of titanium tetra-n-butoxide, 0.2 g of titanium tributoxymonostearate and 2.1 g of maleic anhydride was heated to 40° C., and thereto was slowly added dropwise 3 g of ion exchanged water with stirring. Thereafter, the mixture was heated to 70° C. and stirred for 300 min. To this mixed liquid were added 6.2 g of acetylacetone and 200 g of ethyl lactate, and the mixture was concentrated under a vacuum environment to obtain a solution of a compound (A-5) in ethyl lactate. The concentration of the compound (A-5) in this solution was 18% by mass.

### Synthesis Example 6

To a mixed liquid of 100 g of isopropanol and 11 g of titanium tetraisopropoxide was slowly added dropwise 0.8 g of ion exchanged water. After the mixture was stirred at room temperature for 30 min, the mixture was heated to 50° C. and stirred for 180 min. To this mixed liquid were added 12 g of acetylacetone and 100 g of propylene glycol monomethyl ether, the mixture was concentrated under vacuum to obtain a solution of a compound (A-6) in propylene glycol monomethyl ether. The concentration of the compound (A-6) in this solution was 8% by mass.

### Preparation of Composition for Film Formation

### Examples 1 to 5 and Comparative Examples 1 to 3

A composition for film formation (S-1) was prepared by mixing 25 parts by mass of the solution containing (A-1) as the compound (A), 15 parts by mass (B1-1) as the alcohol solvent (B1), and 60 parts by mass of (B2-1) as the non-alcohol organic solvent (B2), followed by filtration through a fluorine-based filter of 0.1 μm. Compositions for film formation (S-2) to (S-5) and (CS-1) to (CS-3) were prepared in a similar manner using compounds shown in Table 1, and the like.

Compounds used in the preparation of the compositions for film formation according to Examples and Comparative Examples are shown below.

### (B1) Alcohol Solvent

B1-1: propylene glycol-1-methyl ether
B1-2: n-butanol
B1-3: methyl isobutyl carbinol
B1-4: ethyl lactate
B1-5: propylene glycol-1-ethyl ether

### (B2) Non-Alcohol Solvent

B2-1: diisoamyl ether
B2-2: propylene glycol-1-methyl ether acetate
B2-3: butyl acetate
B2-4: 3-methoxybutyl acetate

TABLE 1

| | | | | (B) Solvent composition | | | | | |
|---|---|---|---|---|---|---|---|---|---|
| | | | | (B1) | | (B2) | | | |
| | | (A) | | alcohol | | non-alcohol | | | |
| | | Compound | | solvent | | solvent | | Other additive | |
| | | | using | | using | | using | | using |
| | Composition | | amount | | amount | | amount | | amount |
| | for film | | (parts | | (parts | | (parts | | (parts |
| | formation | | by | | by | | by | | by |
| | type | type | mass) | type | mass) | type | mass) | type | mass) |
| Example 1 | S-1 | A-1 | 25 | B1-1 | 15 | B2-1 | 60 | — | — |
| Example 2 | S-2 | A-2 | 25 | B1-2 | 10 | B2-2 | 65 | — | — |
| Example 3 | S-3 | A-3 | 10 | B1-3 | 5 | B2-2 | 85 | — | — |
| Example 4 | S-4 | A-4 | 10 | B1-1 | 40 | B2-3 | 50 | water | 1.5 |
| Example 5 | S-5 | A-5 | 15 | B1-4 | 15 | B2-4 | 70 | — | — |
| Comparative | CS-1 | A-6 | 25 | B1-1 | 75 | — | — | — | — |
| Example 1 | | | | | | | | | |
| Comparative | CS-2 | A-6 | 15 | B1-1 | 75 | B2-2 | 10 | — | — |
| Example 2 | | | | | | | | | |
| Comparative | CS-3 | A-4 | 10 | B1-5 | 90 | — | — | — | — |
| Example 3 | | | | | | | | | |

### Evaluations

### Change in Molecular Weight

With respect to the compositions for film formation according to Examples and Comparative Examples, the molecular weight immediately after the preparation (initial molecular weight) and the molecular weight after storage at 35° C. for 3 months were determined, and a rate of change in the molecular weight was determined. The results of the determinations are shown in Table 2.

### Change in Film Thickness

Each of the compositions for film formation according to Examples and Comparative Examples was spin-coated, and baked at 250° C. for 1 min to obtain a metal oxide-containing film. With respect to the metal oxide-containing film, the film thickness immediately after the formation (initial film thickness) and the film thickness after storage at 35° C. for 3 months were measured using a spectroscopic ellipsometer (“M-2000” available from J. A. Woollam), whereby a rate of change in the film thickness was determined. The results of the determinations are shown in Table 2.

TABLE 2

| | Composition | Molecular weight | | Film thickness | |
|---|---|---|---|---|---|
| | for film | | rate of | | rate of |
| | formation | | change | initial | change |
| | type | initial | (%) | (nm) | (%) |
| Example 1 | S-1 | 22,000 | +0.5 | 55 | +0.8 |
| Example 2 | S-2 | 9,000 | −0.2 | 32 | +0.0 |
| Example 3 | S-3 | 19,000 | +2.2 | 20 | +1.5 |
| Example 4 | S-4 | 18,000 | −1.2 | 25 | −0.8 |
| Example 5 | S-5 | 31,000 | +1.1 | 40 | +0.2 |
| Comparative | CS-1 | 15,000 | −8.3 | 30 | −7.2 |
| Example 1 | | | | | |
| Comparative | CS-2 | 16,000 | −6.2 | 20 | −7.1 |
| Example 2 | | | | | |
| Comparative | CS-3 | 16,000 | −9.1 | 24 | −5.1 |
| Example 3 | | | | | |

### Amount of Volatilized Inorganic Component

The amount of volatilized inorganic components in each of the compositions for film formation according to Examples and Comparative Examples was determined using the following procedure. First, each composition for film formation was spin-coated on a wafer, and then a silicon wafer was placed so as to face the coated wafer with a spacing therebetween of 0.7 mm. Thereafter, the coated wafer was baked at 250° C. for 1 min, and components volatilized during the baking were trapped by the facing silicon wafer. Inorganic components remained on the surface of the silicon wafer were recovered using a mixed liquid of hydrofluoric acid and nitric acid, and the amount of the volatilized inorganic components was determined by ICP-MS. The results of the determinations are shown in Table 3. It is to be noted that “-” in Table 3 indicates that the volatilized inorganic components were not detected.

TABLE 3

| | | Amount of |
|---|---|---|
| | Composition | trapped |
| | for film | inorganic |
| | formation | components |
| | type | atoms/cm² |
| Example 1 | S-1 | — |
| Example 2 | S-2 | — |
| Example 3 | S-3 | — |
| Example 4 | S-4 | 1.2 × 10⁹ |
| Example 5 | S-5 | — |
| Comparative | CS-1 | 1.2 × 10¹⁰ |
| Example 1 | | |
| Comparative | CS-2 | 9.0 × 10⁹ |
| Example 2 | | |
| Comparative | CS-3 | 1.4 × 10¹⁰ |
| Example 3 | | |

As shown in Table 2, the compositions for film formation according to Examples each exhibited a small rate of change in the molecular weight and a small rate of change in the film thickness, indicating that the compositions for film formation according to Examples exhibit superior storage stability. On the other hand, the compositions for film formation according to Comparative Examples exhibited a greater change in both the molecular weight and the film thickness as compared with those of Examples, indicating that the compositions for film formation according to Comparative Examples are inferior to those of Example s in storage stability.

Moreover, as shown in Table 3, the amount of the volatilized inorganic components of the compositions for film formation according to Examples was smaller as compared with that of the compositions for film formation according to Comparative Examples, and therefore it is found that the compositions for film formation according to Examples are effective for the inhibition of contamination in semiconductor manufacturing apparatuses.

According to the composition for film formation and pattern-forming method, both the superior storage stability and the superior inhibitory ability of volatilization can be exhibited. Therefore, these can be very suitably used in processes for manufacture of LSIs, in particular in the formation of fine contact holes and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

1. A composition for film formation comprising:
a hydrolysis compound which is
a hydrolysis product of a metal compound comprising a hydrolyzable group,
a hydrolytic condensation product of the metal compound,
a condensation product of the metal compound and a compound represented by formula (1), or
a combination thereof; and
a solvent composition,
R¹X¹)ₙ (1)
wherein in the formula (1),
R¹ represents an organic group having a valency of n;
X¹ represents —OH, —COOH, —NCO or —NHR^{a};
R^{a} represents a hydrogen atom or a monovalent organic group;
n is an integer of 2 to 4; and
a plurality of X¹s are identical or different, and
wherein,
the metal compound comprises at least one metal element selected from the group consisting of Cr, Mo, W, Zn, Cd, Hg, B, Al, Ga, and In,
the solvent composition comprises an alcohol organic solvent, and a non-alcohol organic solvent that does not comprise an alcoholic hydroxyl group and that comprises a group comprising a hetero atom,
a content of the alcohol organic solvent with respect to a mass of the solvent composition is no less than 1% by mass and no greater than 50% by mass, and
a content of the non-alcohol organic solvent with respect to the mass of the solvent composition is no less than 50% by mass and no greater than 99% by mass.

2. The composition according to claim 1, wherein an absolute molecular weight of the hydrolysis compound as determined by static light scattering is no less than 6,000 and no greater than 50,000.

3. The composition according to claim 1, wherein the group comprising a hetero atom is —CO—, —O—, —NR—, or a combination thereof, wherein R represents a hydrogen atom or a hydrocarbon group having 1 to 10 carbon atoms.

4. The composition according to claim 1, wherein the metal element is aluminum, tungsten, or molybdenum.

5. The composition according to claim 4, wherein the metal element is tungsten.

6. The composition according to claim 1, wherein the alcohol organic solvent is an alkylene glycol monoalkyl ether.

7. The composition according to claim 6, wherein the alcohol organic solvent is a propylene glycol monoalkyl ether.

8. The composition according to claim 1, wherein the non-alcohol organic solvent is an ester organic solvent, a ketone organic solvent, an amide organic solvent, an ether organic solvent, or a combination thereof.

9. The composition according to claim 8, wherein the non-alcohol organic solvent is a propylene glycol alkyl ether acetate.

10. The composition according to claim 1, wherein the metal compound is represented by formula (2): 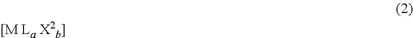
wherein in the formula (2),
M represents at least one metal element selected from the group consisting of Cr, Mo, W, Zn, Cd, Hg, B, Al, Ga, and In;
L represents a ligand;
a is an integer of 0 to 3, wherein in a case where a is no less than 2, a plurality of Ls are identical or different;
X² represents the hydrolyzable group;
b is an integer of 2 to 6;
a plurality of X²s are identical or different; and
a value of a×2+b is no greater than 6.

11. A pattern-forming method comprising:
applying the composition according to claim 1 directly or indirectly on a front face of a substrate to provide an inorganic film;
forming a resist pattern directly or indirectly on a front face of the inorganic film; and
forming a pattern on the substrate by a dry etching using the resist pattern as a mask.

12. The pattern-forming method according to claim 11, further comprising before forming the resist pattern, overlaying an antireflective film directly or indirectly on the front face of the inorganic film.

13. The pattern-forming method according to claim 11, further comprising before providing the inorganic film, providing a resist underlayer film on the front face of the substrate.
